(19) United States
(12) Patent Application Publication
(10) Pub. No.: US 2026/0268991 A1
(43) Pub. Date: Sep. 10, 2026

(54) SHIFT REGISTER UNIT AND DRIVING METHOD THEREFOR, GATE DRIVING CIRCUIT, AND DISPLAY PANEL

(71) Applicants: Hefei BOE Joint Technology Co., Ltd., Anhui (CN); BOE TECHNOLOGY GROUP CO., LTD., Beijing (CN); Beijing BOE Technology Development Co., Ltd., Beijing (CN)

(72) Inventors: Zhidong YUAN, Beijing (CN); Yongqian LI, Beijing (CN); Pan XU, Beijing (CN); Jianwei YU, Beijing (CN)

(21) Appl. No.: 19/154,840

(22) PCT Filed: Dec. 18, 2023
(86) PCT No.: PCT/CN2023/139401

§ 371 Date: Aug. 8, 2025

(51) Int. Cl. G11C 19/28; G09G 3/20

(52) U.S. Cl. CPC G11C 19/28; G09G 3/20; G09G 2310/0286; G09G 2310/08; G09G 2340/0435

(57) ABSTRACT

This disclosure provides a shift register unit, a driving method, a gate driver circuit, and a display panel. The shift register unit includes: a node setting circuit; a preprocessing circuit configured to input an effective level to a second node, and to transmit a signal from a second clock signal terminal to the second node; a gating circuit configured to transmit a signal from a third clock signal terminal to a third node through any gating signal terminal; an input circuit configured to transmit a signal from a fourth clock signal terminal to each control signal terminal; a separation circuit; and an output circuit configured to transmit, according to a signal from the control signal terminal, a signal from the corresponding output clock signal terminal to the corresponding signal output terminal, and to transmit the signal from the second power supply terminal to each signal output terminal.

### CROSS-REFERENCE TO RELATED APPLICATIONS

The present application is the U.S. National phase application of International Application No. PCT/CN2023/139401, filed on Dec. 18, 2023, the entire contents of which are hereby incorporated by reference in its entirety.

### TECHNICAL FIELD

This disclosure relates to the field of display technologies, and in particular, to a shift register unit, a driving method of the shift register unit, a gate driver circuit, and a display panel.

### BACKGROUND

In related technologies, in order to balance the display quality and power consumption of a display panel, the display area of the display panel is generally divided into multiple partitions, and different refresh rates are set for different partitions. However, after the partitions are divided in the related technologies, the positions of the partitions cannot be changed anymore, meaning that the refresh rates of different positions of the display panel cannot be adjusted according to demand.

It should be noted that the above information disclosed in the “BACKGROUND” section is intended only to enhance the understanding of the background of this disclosure, and therefore it may include information that does not constitute prior art known to those of ordinary skill in the art.

### SUMMARY

According to an aspect of the present disclosure, a shift register unit is provided. The shift register unit includes:
a node setting circuit, connected to a third clock signal terminal and a first node, and configured to input an effective level to the first node in response to a signal from the third clock signal terminal;
a preprocessing circuit, connected to a second clock signal terminal, a second node, and a third node, and configured to input an effective level to the second node in response to a signal from the second clock signal terminal, and to transmit the signal from the second clock signal terminal to the second node in response to a signal from the third node;
a gating circuit, connected to the third node, the third clock signal terminal, and one or more gating signal terminals, and configured to transmit the signal from the third clock signal terminal to the third node in response to a signal from one of the one or more gating signal terminals;
an input circuit, connected to a fourth clock signal terminal, the second node, and one or more of a plurality of control signal terminals, and configured to transmit a signal from the fourth clock signal terminal to the one or more control signal terminals in response to a signal from the second node;
a separation circuit, connected to the first node, the plurality of control signal terminals, and a second power supply terminal, and configured to transmit a signal from the second power supply terminal to the plurality of control signal terminals in response to a signal from the first node; and
an output circuit, connected to the plurality control signal terminals, a plurality of output clock signal terminals, a plurality of signal output terminals, and the second power supply terminal, wherein the plurality of control signal terminals are provided in correspondence with the plurality of output clock signal terminals, and the plurality of control signal terminals are provided in correspondence with the plurality of signal output terminals; and the output circuit is configured to transmit, according to a signal from the control signal terminal, a signal from the output clock signal terminal corresponding to the control signal terminal to the signal output terminal corresponding to the control signal terminal, and to transmit the signal from the second power supply terminal to the plurality of signal output terminals in response to the signal from the first node.

In an exemplary embodiment of the present disclosure, the shift register unit further includes:
a first pull-down circuit, connected to the third node and the second clock signal terminal, and configured to input an invalid level to the third node in response to the signal from the second clock signal terminal.

In an exemplary embodiment of the present disclosure, the shift register unit further includes:
a first storage circuit, connected to the third node, and configured to store a voltage at the third node.

In an exemplary embodiment of the present disclosure, the shift register unit further includes:
a reset circuit, connected to a first power supply terminal, the first node, the second node, the second power supply terminal, and a reset signal terminal, and configured to transmit a signal from the first power supply terminal to the first node in response to a signal from the reset signal terminal, and to transmit the signal from the second power supply terminal to the second node in response to the signal from the reset signal terminal.

In an exemplary embodiment of the present disclosure, the shift register unit further includes:
a second pull-down circuit, connected to one of the plurality of control signal terminals and the first node, and configured to input an invalid level to the first node in response to a signal from the control signal terminal.

In an exemplary embodiment of the present disclosure, the node setting circuit is further connected to the fourth clock signal terminal and the second node, and configured to input an invalid level to the first node in response to the signal from the fourth clock signal terminal and the signal from the second node.

In an exemplary embodiment of the present disclosure, the node setting circuit is configured to provide the effective level to the first node using the third clock signal terminal in response to the signal from the third clock signal terminal.

In an exemplary embodiment of the present disclosure, the node setting circuit is configured to provide the invalid level to the first node using the third clock signal terminal in response to the signal from the fourth clock signal terminal and the signal from the second node.

In an exemplary embodiment of the present disclosure, the first pull-down circuit is further connected to the third clock signal terminal, and configured to input the invalid level to the third node using the third clock signal terminal in response to the signal from the second clock signal terminal.

In an exemplary embodiment of the present disclosure, the second pull-down circuit is further connected to the third clock signal terminal, and configured to input the invalid level to the first node using the third clock signal terminal in response to the signal from the control signal terminal.

In an exemplary embodiment of the present disclosure, the preprocessing circuit is configured to provide the effective level to the second node using the second clock signal terminal in response to the signal from the second clock signal terminal.

In an exemplary embodiment of the present disclosure, the node setting circuit includes:
a first transistor, with a first electrode connected to the third clock signal terminal, a second electrode connected to the first node, and a gate connected to the third clock signal terminal;
a second transistor, with a first electrode connected to the first node, and a gate connected to the second node;
a third transistor, with a first electrode connected to a second electrode of the second transistor, and a second electrode connected to the third clock signal terminal; and
a third capacitor, with a first electrode connected to the first node, and a second electrode connected to a stable voltage terminal.

In an exemplary embodiment of the present disclosure, the preprocessing circuit includes:
a fourth transistor, with a first electrode connected to the second clock signal terminal, a second electrode connected to the second node, and a gate connected to the second clock signal terminal;
a fifth transistor, with a first electrode connected to the second clock signal terminal, a second electrode connected to the second node, and a gate connected to the third node; and
a second capacitor, with a first electrode connected to the second node, and a second electrode connected to a stable voltage terminal.

In an exemplary embodiment of the present disclosure, the gating circuit includes:
one or more gating transistors, wherein the one or more gating transistors are provided in correspondence with the one or more gating signal terminals; and a first electrode of the gating transistor is connected to the third clock signal terminal, a second electrode of the gating transistor is connected to the third node, and a gate of the gating transistor is connected to the gating signal terminal corresponding to the gating transistor.

In an exemplary embodiment of the present disclosure, the input circuit includes:
a sixth transistor, with a first electrode connected to the fourth clock signal terminal, a second electrode connected to a fourth node, and a gate connected to the second node; and
one or more input transistors, wherein the one or more input transistors are provided in correspondence with the one or more control signal terminals; and a first electrode of the input transistor is connected to the fourth node, a second electrode of the input transistor is connected to the control signal terminal corresponding to the input transistor, and a gate of the input transistor is connected to the fourth clock signal terminal.

In an exemplary embodiment of the present disclosure, the separation circuit includes:
one or more separation transistors provided in correspondence with the plurality of control signal terminal, wherein a first electrode of the separation transistor is connected to the second power supply terminal, a second electrode of the separation transistor is connected to the control signal terminal corresponding to the separation transistor, and a gate of the separation transistor is connected to the first node.

In an exemplary embodiment of the present disclosure, the output circuit includes:
one or more first output transistors provided in correspondence with the plurality of control signal terminals, wherein a gate of the first output transistor is connected to the control signal terminal corresponding to the first output transistor, a first electrode of the first output transistor is connected to the output clock signal terminal corresponding to the first output transistor, and a second electrode of the first output transistor is connected to the signal output terminal corresponding to the first output transistor;
one or more second output transistors provided in correspondence with the plurality of signal output terminals, wherein a gate of the second output transistor is connected to the first node, a first electrode of the second output transistor is connected to the second power supply terminal, and a second electrode of the second output transistor is connected to the signal output terminal corresponding to the second output transistor; and
one or more output capacitors provided in correspondence with the plurality of control signal terminals, wherein a first electrode of the output capacitor is connected to the control signal terminal corresponding to the output capacitor, and a second electrode of the output capacitor is connected to the signal output terminal corresponding to the output capacitor;
wherein, the first output transistor and the output clock signal terminal corresponding to the same control signal terminal are provided in correspondence with each other, the first output transistor and the signal output terminal corresponding to the same control signal terminal are provided in correspondence with each other, and the output capacitor and the signal output terminal corresponding to the same control signal terminal are provided in correspondence with each other.

In an exemplary embodiment of the present disclosure, the first pull-down circuit includes:
a seventh transistor, with a first electrode connected to the third clock signal terminal, a second electrode connected to the third node, and a gate connected to the second clock signal terminal.

In an exemplary embodiment of the present disclosure, the first storage circuit includes:
a first capacitor, with a first electrode connected to the third node, and a second electrode connected to a stable voltage terminal.

In an exemplary embodiment of the present disclosure, the reset circuit includes:
an eighth transistor, with a first electrode connected to the first power supply terminal, a second electrode connected to the first node, and a gate connected to the reset signal terminal; and
a ninth transistor, with a first electrode connected to the second power supply terminal, a second electrode connected to the second node, and a gate connected to the reset signal terminal.

In an exemplary embodiment of the present disclosure, the second pull-down circuit includes:
a tenth transistor, with a first electrode connected to the third clock signal terminal, a second electrode connected to the first node, and a gate connected to the control signal terminal.

In an exemplary embodiment of the present disclosure, in a same shift register unit, types of a plurality of gating transistors are the same or different.

According to an aspect of the present disclosure, a driving method of a shift register unit is provided, which is used to drive the shift register unit described above. The driving method includes:
in a first phase, inputting the effective level to the second node using the preprocessing circuit;
in a second phase, when the shift register unit is selected, turning off a connection between the third clock signal terminal and the third node using the gating circuit; when the shift register unit is not selected, turning on the connection between the third clock signal terminal and the third node using the gating circuit;
in a third phase, when the shift register unit is selected, transmitting the signal from the fourth clock signal terminal to the one or more control signal terminals using the input circuit; when the shift register unit is not selected, turning off an connection between the fourth clock signal terminal and each of the one or more control signal terminals using the input circuit;
in a fourth phase, when the shift register unit is selected, transmitting, according to the signal from the control signal terminal, the signal from the output clock signal terminal corresponding to the control signal terminal to the signal output terminal corresponding to the control signal terminal using the output circuit; when the shift register unit is not selected, turning off an connection between the fourth clock signal terminal and each of the plurality of signal output terminals using the output circuit, and transmitting the signal from the second power supply terminal to the signal output terminal using the output circuit; and
in a fifth phase, transmitting the signal from the second power supply terminal to the plurality of control signal terminals using the separation circuit, and transmitting the signal from the second power supply terminal to the plurality of signal output terminals using the output circuit.

According to an aspect of the present disclosure, a gate driver circuit is provided. The gate driver circuit includes a plurality of shift register units as described above.

In an exemplary embodiment of the present disclosure, the gate driver circuit includes a plurality of shift register groups, each shift register group includes one or more of the plurality of shift register units; and
the gate driver circuit further includes:
a plurality of gating signal lines, wherein in a same shift register unit, different gating signal terminals are respectively connected to different gating signal lines;
in a same shift register group, the shift register units are connected to a same gating signal line; and
in different shift register groups, at least one of the gating signal lines connected to the shift register units is different.

In an exemplary embodiment of the present disclosure, in different shift register groups, at least a portion of the plurality of shift register units are connected to a same gating signal line.

In an exemplary embodiment of the present disclosure, the shift register unit includes n gating signal terminals, the gate driver circuit includes 2ⁿ shift register groups and n pairs of gating signal lines, each pair of gating signal lines includes two gating signal lines, and the two gating signal lines in a same pair of gating signal lines are respectively connected to 2ⁿ/2 shift register groups; and
the n gating signal terminals in the shift register unit are provided in one-to-one correspondence with the n pairs of gating signal lines, and the gating signal terminal is selectively connected to one of the gating signal lines in the corresponding pair of gating signal lines; and
wherein, polarities of the two gating signal lines in the same pair of gating signal lines are opposite, n being an integer greater than or equal to 1.

In an exemplary embodiment of the present disclosure, when n is greater than or equal to 2,
the n pairs of gating signal lines include a first pair of gating signal lines to an n^{th} pair of gating signal lines, and among multiple shift register groups that are simultaneously connected to a same gating signal line in the first to an i^{th} pairs of gating signal lines, half of the multiple shift register groups are connected to one of the gating signal lines in a (i+1)^{th} pair of gating signal lines, and the other half of the multiple shift register groups are connected to the other gating signal line in the (i+1)^{th} pair of gating signal lines, i being an integer greater than or equal to 1 and less than or equal to n−1.

In an exemplary embodiment of the present disclosure, when the gating circuit includes:
one or more gating transistors, the one or more gating transistors are provided in correspondence with the one or more gating signal terminals, a first electrode of the gating transistor is connected to the third clock signal terminal, a second electrode of the gating transistor is connected to the third node, and a gate of the gating transistor is connected to the gating signal terminal corresponding to the gating signal terminal;
the gate driver circuit includes a plurality of shift register groups, each shift register group including one or more of the plurality of shift register units; and
in different shift register groups, at least a portion of the plurality of shift register units have different combinations of types of gating transistors.

In an exemplary embodiment of the present disclosure, the shift register unit includes n gating signal terminals, the gate driver circuit includes 2ⁿ shift register groups and n gating signal lines, the n gating signal terminals are provided in correspondence with the n gating signal lines, and the gating signal terminal is connected to the corresponding gating signal line; and
the shift register units in different shift register groups have different combinations of types of gating transistors.

In an exemplary embodiment of the present disclosure, a same gating signal line is connected to 2ⁿ/2 N-type transistors and 2ⁿ/2 P-type transistors; and among multiple shift register groups that are simultaneously connected to a first to an i^{th} gating signal lines and have a same type of gating transistors connected to a same gating signal line, half of the gating transistors connected to a (i+1)^{th} gating signal line are N-type transistors and the other half of the gating transistors connected to the (i+1)^{th} gating signal line are P-type transistors, i being an integer greater than or equal to 1 and less than or equal to n−1.

In an exemplary embodiment of the present disclosure, the number of shift register units in different shift register groups is the same or different.

According to an aspect of the present disclosure, a display panel is provided. The display panel includes the gate driver circuit described above.

It should be understood that the above general description and the following detailed descriptions are exemplary and explanatory only and do not limit the present disclosure.

### BRIEF DESCRIPTION OF THE DRAWINGS

The accompanying drawings herein are incorporated into and form part of the specification, show some of embodiments that are consistent with the present disclosure, and are used in conjunction with the specification to explain the principles of the present disclosure. It is obvious that the accompanying drawings in the following description are only some of embodiments of the present disclosure, and that other drawings may be obtained from them without creative effort by one of ordinary skill in the art.

FIG. 1 is a structural schematic diagram of a display panel according to an exemplary embodiment of the present disclosure.

FIG. 2 is a structural schematic diagram of a gate driver circuit according to an exemplary embodiment of the present disclosure.

FIG. 3 is a structural schematic diagram of a shift register unit according to an exemplary embodiment of the present disclosure.

FIG. 4 is a structural schematic diagram of a portion of the gate driver circuit of the present disclosure.

FIG. 5 is a timing diagram when a first-stage shift register unit in the gate driver circuit shown in FIG. 4 is selected.

FIG. 6 is a timing diagram of eight pairs of gating signal lines in the timing diagram shown in FIG. 5.

FIG. 7 is a structural schematic diagram of a shift register unit according to an exemplary embodiment of the present disclosure.

FIG. 8 is a structural schematic diagram of a node setting circuit of a shift register unit according to another exemplary embodiment of the present disclosure.

### DETAILED DESCRIPTION

Exemplary embodiments will now be described more fully with reference to the accompanying drawings. However, the exemplary embodiments can be implemented in a variety of forms and should not be construed as being limited to the examples set forth herein; rather, the provision of these embodiments makes the present disclosure comprehensive and complete and conveys the concept of the exemplary embodiments to those skilled in the art in a comprehensive manner. The same reference numerals in the drawings indicate the same or similar structures, and thus their detailed description will be omitted.

In the description of the present disclosure, unless otherwise clearly defined and limited, the terms “first” and “second” are only used for the purpose of description, and cannot be construed as indicating or implying relative importance. The term “a plurality of” or “multiple” means two or more. The term “and/or” includes any and all combinations of one or more of the associated listed items. In particular, references to “the/said” object or “a/an” object are equally intended to indicate one of a possible plurality of such objects.

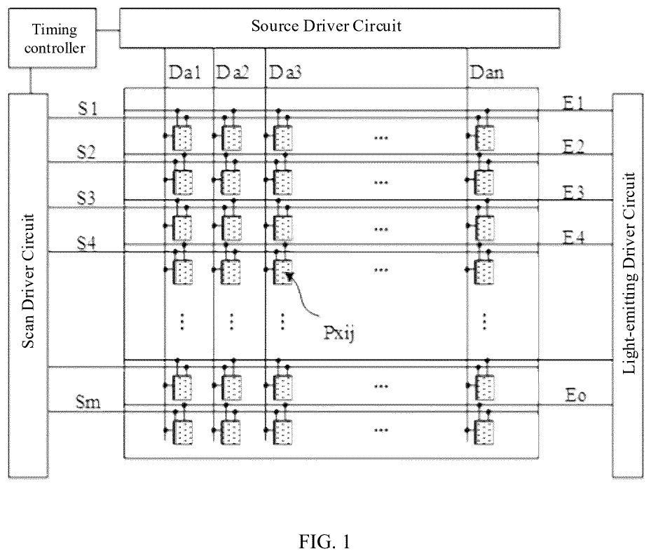

As shown in FIG. 1, it is a structural schematic diagram of a display panel according to an exemplary embodiment of the present disclosure. The display panel may include a timing controller, a source driver circuit, a gate driver circuit, and a pixel array. The timing controller is respectively connected to the source driver circuit and the gate driver circuit, and the source driver circuit is respectively connected to a plurality of data signal lines (Da1 to Dan). The gate driver circuit includes a scan driver circuit and a light-emitting driver circuit. The scan driver circuit is respectively connected to a plurality of scan signal lines (S1 to Sm). The light-emitting driver circuit is respectively connected to a plurality of light-emitting signal lines (E1 to Eo). The pixel array may include a plurality of sub-pixels Pxij, where i and j can be natural numbers. At least one sub-pixel Pxij may include a circuit unit and a light-emitting device connected to the circuit unit. The circuit unit may include a pixel driving circuit, and the pixel driving circuit may be connected to the scan signal line, the light-emitting signal line, and the data signal line, respectively. In an exemplary embodiment, the timing controller can provide grayscale values and control signals suitable for the specifications of the source driver circuit to the source driver circuit, can provide clock signals, scan start signals, etc. suitable for the specifications of the scan driver circuit to the scan driver circuit, and can provide clock signals, emission stop signals, etc. suitable for the specifications of the light-emitting driver circuit to the light-emitting driver circuit. The source driver circuit can use the grayscale values and control signals received from the timing controller to generate data voltages to be provided to the data signal lines Da1, Da2, Da3 and Dan. For example, the source driver circuit can sample the grayscale values using the clock signal and apply the data voltages corresponding to the grayscale values to the data signal lines Da1 to Dan on a per-pixel-row basis, where n can be a natural number. The scan driver circuit can generate scan signals to be provided to the scan signal lines S1, S2, S3, . . . and Sm through the clock signals, scan start signals, etc. received from the timing controller. For example, the scan driver circuit can sequentially provide scan signals with conduction-level pulses to the scan signal lines S1 to Sm. For example, the scan driver circuit can be configured in the form of a shift register and can generate scan signals by sequentially transmitting the scan start signals provided in the form of conduction-level pulses to the next-stage circuit under the control of the clock signal, where m can be a natural number. The light-emitting driver circuit can generate emission signals to be provided to the light-emitting signal lines E1, E2, E3, . . . and Eo through clock signals, emission stop signals, etc. received from the timing controller. For example, the light-emitting driver circuit can sequentially provide emission signals with cut-off-level pulses to the light-emitting signal lines E1 to Eo. For example, the light-emitting driver circuit can be configured in the form of a shift register and can generate emission signals by sequentially transmitting the emission stop signals provided in the form of cut-off-level pulses to the next-stage circuit under the control of the clock signal, where o can be a natural number.

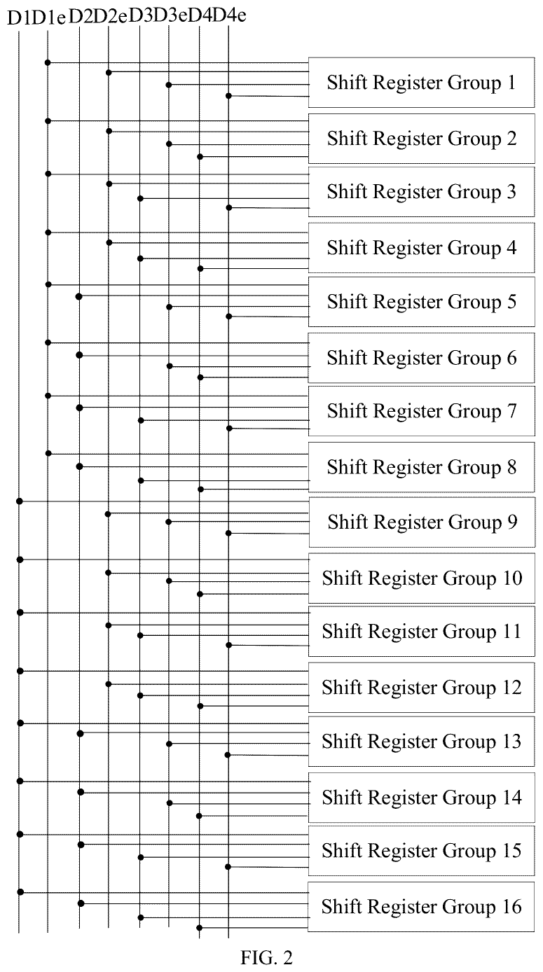

According to an exemplary embodiment, a gate driver circuit is provided. As shown in FIG. 2, it is a structural schematic diagram of a gate driver circuit according to an exemplary embodiment of the present disclosure. The gate driver circuit may include a plurality of shift register groups, and each shift register group may include one or more shift register units. In this exemplary embodiment, 16 shift register groups are taken as an example for illustration. The 16 shift register groups include shift register group 1 to shift register group 16. Correspondingly, the gate driver circuit may include 4 pairs of gating signal lines. Each pair of gating signal lines includes two gating signal lines. The first pair of gating signal lines may include gating signal lines D1 and D1e, the second pair of gating signal lines may include gating signal lines D2 and D2e, the third pair of gating signal lines may include gating signal lines D3 and D3e, and the fourth pair of gating signal lines may include gating signal lines D4 and D4e. The gating signal line D1 can be connected to shift register groups 9-16, and the gating signal line D1e can be connected to shift register groups 1-8. The gating signal line D2 can be connected to shift register groups 5-8 and shift register groups 13-16, and the gating signal line D2e can be connected to shift register groups 1-4 and 9-12. The gating signal line D3 can be connected to shift register groups 3, 4, 7, 8, 11, 12, 15, and 16, and the gating signal line D3e can be connected to shift register groups 1, 2, 5, 6, 9, 10, 13, and 14. The gating signal line D4 can be connected to shift register groups 2, 4, 6, 8, 10, 12, 14, and 16, and the gating signal line D4e can be connected to shift register groups 1, 3, 5, 7, 9, 11, 13, and 15. In the same shift register group, the gating signal lines connected to the shift register units can be the same.

In this exemplary embodiment, the combination of gating signal lines connected to each shift register group is different, that is, at least one of the gating signal lines connected to different shift register groups is different. The polarities of the two gating signal lines in the same pair of gating signal lines are opposite. In this exemplary embodiment, any one of shift register groups can be selected by controlling the polarities of the gating signal lines in the 4 pairs of gating signal lines. The selected shift register group can normally output the gate driving signal, and the unselected shift register group does not output the gate driving signal. Thus, this exemplary embodiment can control the refresh rate of the pixel driving circuit connected to any one of shift register groups.

It should be understood that in other exemplary embodiments, the number of shift register groups can also be other values. Any of 2ⁿ shift register groups can be controlled by n pairs of gating signal lines, where n is an integer greater than or equal to 1. For example, n can be equal to 1, 2, 3, 4, 5, 6, 7, 8, etc.

In this exemplary embodiment, n can be greater than or equal to 2. The n pairs of gating signal lines include the first pair of gating signal lines to the n^{th} pair of gating signal lines. Among a plurality of shift register groups that are simultaneously connected to the same gating signal line in the first to the i^{th} pairs of gating signal lines, half of the shift register groups are connected to one of the gating signal lines in the (i+1)^{th} pair of gating signal lines, and the other half of the shift register groups are connected to the other gating signal line in the (i+1)^{th} pair of gating signal lines, where i is an integer greater than or equal to 1 and less than or equal to n−1. For example, as shown in FIG. 2, among the shift register groups 1-4 connected to the gating signal lines D1e and D2e, shift register groups 1-2 are connected to D3e, and shift register groups 3-4 are connected to D3.

It should be understood that in other exemplary embodiments, the number of gating signal lines in the gate driver circuit can also be other values, and there can be other connection methods between the gating signal lines and the shift register groups as long as it is ensured that at least one of the gating signal lines connected to different shift register groups is different, that is, any one of shift register groups can be selected through the polarities of the gating signal lines. In addition, in different shift register groups, at least a portion of the shift register groups can be connected to the same gating signal line. This setting can reduce the number of gating signal lines. FIG. 2 shows a specific way of sharing gating signal lines by shift register groups, and the gate driver circuit provided by the present disclosure is not limited to this way of sharing gating signal lines.

The gate driver circuit provided in this exemplary embodiment can be used in the scan driver circuit and the light-emitting driver circuit in FIG. 1.

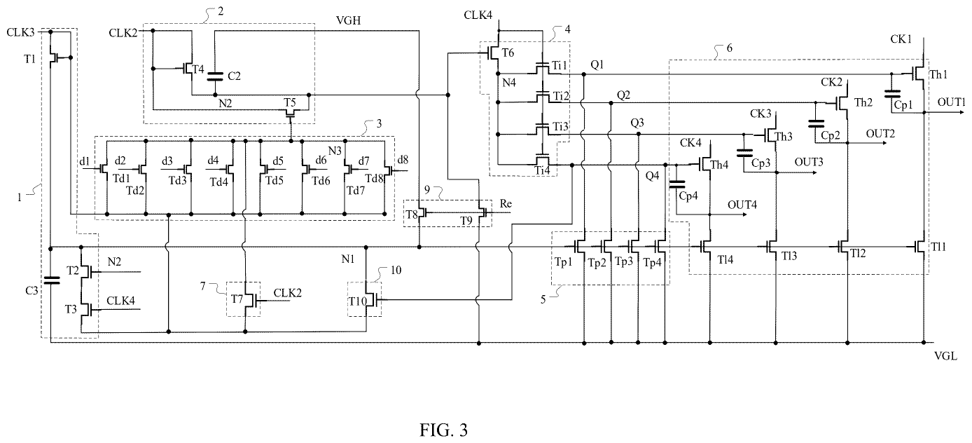

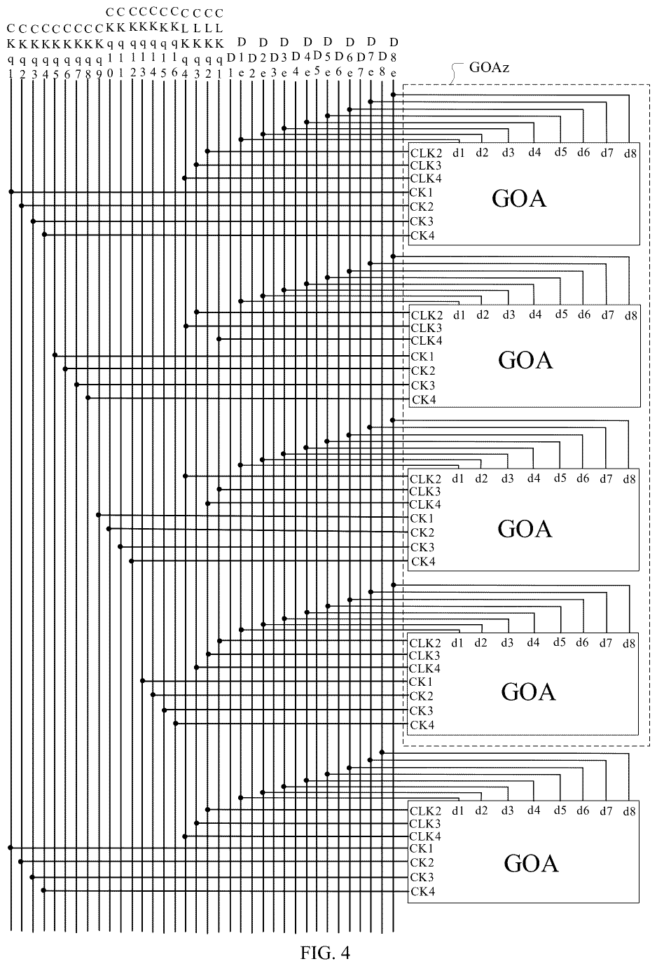

According to an exemplary embodiment, a shift register unit is also provided. As shown in FIGS. 3 and 4, FIG. 3 is a structural schematic diagram of a shift register unit according to an exemplary embodiment of the present disclosure, and FIG. 4 is a structural schematic diagram of a portion of a gate driver circuit of the present disclosure. The gate driver circuit shown in FIG. 4 includes a plurality of shift register units as shown in FIG. 3. In this gate driver circuit, each shift register group GOAz can include 4 shift register units GOA. The shift register unit includes: a node setting circuit 1, a preprocessing circuit 2, a gating circuit 3, an input circuit 4, a separation circuit 5, and an output circuit 6. The node setting circuit 1 is connected to a third clock signal terminal CLK3 and a first node N1, and is configured to input an effective level to the first node N1 in response to a signal from the third clock signal terminal CLK3. The preprocessing circuit 2 is connected to a second clock signal terminal CLK2, a second node N2, and a third node N3, and is configured to input an effective level to the second node N2 in response to a signal from the second clock signal terminal CLK2, and to transmit the signal from the second clock signal terminal CLK2 to the second node N2 in response to a signal from the third node N3. The gating circuit 3 is connected to the third node N3, the third clock signal terminal CLK3, and 8 gating signal terminals d1-d8, and is configured to transmit the signal from the third clock signal terminal CLK3 to the third node N3 in response to a signal from any one of the gating signal terminals. The input circuit 4 is connected to a fourth clock signal terminal CLK4, the second node N2, and 4 control signal terminals Q1-Q4, and is configured to transmit a signal from the fourth clock signal terminal CLK4 to each of the control signal terminals Q1-Q4 in response to a signal from the second node N2. The separation circuit 5 is connected to the first node N1, the plurality of control signal terminals Q1-Q4, and a second power supply terminal VGL, and is configured to transmit a signal from the second power supply terminal VGL to each of the control signal terminals Q1-Q4 in response to a signal from the first node N1. The output circuit 6 is connected to the plurality of control signal terminals Q1-Q4, a plurality of output clock signal terminals CK1-CK4, a plurality of signal output terminals OUT1-OUT4, and the second power supply terminal VGL. The plurality of control signal terminals Q1-Q4 are provided in one-to-one correspondence with the plurality of output clock signal terminals CK1-CK4, and the plurality of control signal terminals Q1-Q4 are provided in one-to-one correspondence with the plurality of signal output terminals OUT1-OUT4. The output circuit 6 is configured to transmit, according to a signal from the control signal terminal, a signal from the output clock signal terminal corresponding to the control signal terminal to the signal output terminal corresponding to the control signal terminal, and is configured to to transmit the signal from the second power supply terminal VGL to each of the signal output terminals OUT1-OUT4 in response to the signal from the first node N1.

The shift register unit provided in this exemplary embodiment can, in the first phase, input an effective level to the second node N2 using the preprocessing circuit 2; in the second phase, when the shift register unit is selected, turn off the connection between the third clock signal terminal CLK3 and the third node N3 using the gating circuit 3, and when the shift register unit is not selected, turn on the connection between the third clock signal terminal CLK3 and the third node N3 using the gating circuit 3, so as to input an effective level to the third node N3 through the third clock signal terminal CLK3, and then transmit an invalid level of the second clock signal terminal CLK2 to the second node N2 through the preprocessing circuit 2; in the third phase, when the shift register unit is selected, transmit an effective level of the fourth clock signal terminal CLK4 to each of the control signal terminals Q1-Q4 using the input circuit 4 in response to the effective level of the second node N2, and when the shift register unit is not selected, turn off the connection between the fourth clock signal terminal CLK4 and each of the control signal terminals Q1-Q4 using the input circuit 4; in the fourth phase, when the shift register unit is selected, transmit, in response to an effective level of the control signal terminal, a signal from the output clock signal terminal corresponding to the control signal terminal to the signal output terminal corresponding to the control signal terminal, and when the shift register unit is not selected, turn off the connection between the fourth clock signal terminal and each of the signal output terminals using the output circuit, and at the same time, transmit an invalid level of the second power supply terminal VGL to the signal output terminal using the output circuit 6; and in the fifth phase, transmit the invalid level of the second power supply terminal VGL to each of the control signal terminals using the separation circuit 5, and at the same time, transmit the invalid level of the second power supply terminal VGL to each of the signal output terminals using the output circuit 6. In this exemplary embodiment, in the second phase, when any one of the gating signal terminals in a shift register unit is at an effective level, this shift register unit will not be selected. Only when all the gating signal terminals in the shift register unit are at an invalid level, the shift register unit is selected. Thus, the shift register unit can be controlled whether to be gated or not through a plurality of gating signal terminals according to this exemplary embodiment.

It should be noted that the effective level is a level that can turn on a target circuit, and the invalid level is a level that can turn off the target circuit. For example, the effective level corresponding to an N-type transistor is a high level, and the invalid level corresponding to an N-type transistor is a low level.

In this exemplary embodiment, each of the gating signal terminals d1-d8 can be connected to one gating signal line. Correspondingly, the gate driver circuit can include 8 pairs of gating signal lines. The gating signal terminals are provided in correspondence with the pairs of gating signal lines, and the gating signal terminal is selectively connected to one of the gating signal lines in the corresponding pair of gating signal lines.

It should be understood that in other exemplary embodiments, the shift register unit can also include other numbers of gating signal terminals. For example, the shift register unit includes n gating signal terminals, and the gate driver circuit includes 2ⁿ shift register groups and n pairs of gating signal lines. Each pair of gating signal lines includes two gating signal lines, and the two gating signal lines in the same pair of gating signal lines are respectively connected to 2ⁿ/2 shift register groups. The n gating signal terminals in the shift register unit are provided in one-to-one correspondence with the n pairs of gating signal lines, and the gating signal terminal is selectively connected to one of the gating signal lines in the corresponding pair of gating signal lines, where the polarities of the two gating signal lines in the same pair of gating signal lines are opposite, and n is an integer greater than or equal to 1.

In this exemplary embodiment, the numbers of the control signal terminals, the signal output terminals, and the output clock signal terminals can be the same. There can be 4 control signal terminals, 4 signal output terminals, and 4 output clock signal terminals. It should be understood that in other exemplary embodiments, the numbers of the control signal terminals, the signal output terminals, and the output clock signal terminals can also be other values. Each signal output terminal can be connected to a row of pixel driving circuits.

In this exemplary embodiment, as shown in FIG. 3, the shift register unit can also include a first pull-down circuit 7. The first pull-down circuit 7 is connected to the third node N3 and the second clock signal terminal CLK2, and is configured to input an invalid level to the third node N3 in response to the signal from the second clock signal terminal CLK2.

In this exemplary embodiment, as shown in FIG. 3, the shift register unit can also include a reset circuit 9. The reset circuit 9 is connected to a first power supply terminal VGH, the first node N1, the second node N2, the second power supply terminal VGL, and a reset signal terminal Re. The reset circuit 9 is configured to transmit a signal from the first power supply terminal VGH to the first node N1 in response to a signal from the reset signal terminal Re, and to transmit the signal from the second power supply terminal VGL to the second node N2 in response to the signal from the reset signal terminal Re.

In this exemplary embodiment, as shown in FIG. 3, the shift register unit can also include a second pull-down circuit 10. The second pull-down circuit 10 is connected to any one of the control signal terminals and the first node N1, and is configured to input an invalid level to the first node N1 in response to the signal from the control signal terminal.

In this exemplary embodiment, as shown in FIG. 3, the node setting circuit 1 is also connected to the fourth clock signal terminal CLK4 and the second node N2. The node setting circuit 1 can be configured to input an invalid level to the first node N1 in response to the signals from the fourth clock signal terminal CLK4 and the second node N2. The node setting circuit 1 can also be configured to provide an effective level to the first node N1 using the third clock signal terminal CLK3 in response to the signal from the third clock signal terminal CLK3. This setting can reduce the voltage difference between the first node N1 and the third clock signal terminal CLK3 during at least some periods, thereby reducing the leakage current at the first node N1.

In this exemplary embodiment, as shown in FIG. 3, the first pull-down circuit 7 is also connected to the third clock signal terminal CLK3. The first pull-down circuit 7 is configured to input an invalid level to the third node N3 using the third clock signal terminal CLK3 in response to the signal from the second clock signal terminal CLK2. The second pull-down circuit 10 is also connected to the third clock signal terminal CLK3. The second pull-down circuit 10 is configured to input an invalid level to the first node N1 using the third clock signal terminal CLK3 in response to the signal from the control signal terminal. The preprocessing circuit 2 is configured to provide an effective level to the second node N2 using the second clock signal terminal CLK2 in response to the signal from the second clock signal terminal CLK2.

In this exemplary embodiment, as shown in FIG. 3, the node setting circuit 1 includes a first transistor T1, a second transistor T2, a third transistor T3, and a third capacitor C3. A first electrode of the first transistor T1 is connected to the third clock signal terminal CLK3, a second electrode of the first transistor T1 is connected to the first node N1, and a gate of the first transistor T1 is connected to the third clock signal terminal CLK3. A first electrode of the second transistor T2 is connected to the first node N1, and a gate of the second transistor T2 is connected to the second node N2. A first electrode of the third transistor T3 is connected to a second electrode of the second transistor T2, and a second electrode of the third transistor T3 is connected to the third clock signal terminal CLK3. A first electrode of the third capacitor C3 is connected to the first node N1, and a second electrode of the third capacitor C3 is connected to a stable voltage terminal. For example, the second electrode of the third capacitor C3 can be connected to the second power supply terminal VGL.

In this exemplary embodiment, as shown in FIG. 3, the preprocessing circuit 2 can include a fourth transistor T4, a fifth transistor T5, and a second capacitor C2. A first electrode of the fourth transistor T4 is connected to the second clock signal terminal CLK2, a second electrode of the fourth transistor T4 is connected to the second node N2, and a gate of the fourth transistor T4 is connected to the second clock signal terminal CLK2. A first electrode of the fifth transistor T5 is connected to the second clock signal terminal CLK2, a second electrode of the fifth transistor T5 is connected to the second node N2, and a gate of the fifth transistor T5 is connected to the third node N3. A first electrode of the second capacitor C2 is connected to the second node N2, and a second electrode of the second capacitor C2 is connected to a stable voltage terminal. For example, the second electrode of the second capacitor C2 can be connected to the first power supply terminal VGH.

In this exemplary embodiment, as shown in FIG. 3, the gating circuit 3 can include 8 gating transistors Td1-Td8. The gating transistors are provided in one-to-one correspondence with the gating signal terminals. A first electrode of the gating transistor is connected to the third clock signal terminal CLK3, a second electrode of the gating transistor is connected to the third node N3, and a gate of the gating transistor is connected to the gating signal terminal corresponding to the gating transistor. The number of gating transistors can also be other values, and the number of gating transistors is the same as the number of gating signal terminals.

In this exemplary embodiment, as shown in FIG. 3, the input circuit 4 can include a sixth transistor T6 and four input transistors Ti1-Ti4. A first electrode of the sixth transistor T6 is connected to the fourth clock signal terminal CLK4, a second electrode of the sixth transistor T6 is connected to the fourth node N4, and a gate of the sixth transistor T6 is connected to the second node N2. The input transistors are provided in one-to-one correspondence with the control signal terminals. A first electrode of the input transistor is connected to the fourth node N4, a second electrode of the input transistor is connected to the control signal terminal corresponding to the input transistor, and a gate of the input transistor is connected to the fourth clock signal terminal CLK4. The number of input transistors can also be other values, and the number of input transistors is the same as the number of control signal terminals.

In this exemplary embodiment, as shown in FIG. 3, the separation circuit 5 includes four separation transistors Tp1-Tp4. The separation transistors are provided in one-to-one correspondence with the control signal terminals. A first electrode of the separation transistor is connected to the second power supply terminal VGL, a second electrode of the separation transistor is connected to the control signal terminal corresponding to the separation transistor, and a gate of the separation transistor is connected to the first node N1. The number of separation transistors can also be other values, and the number of separation transistors is the same as the number of control signal terminals.

In this exemplary embodiment, as shown in FIG. 3, the output circuit 6 includes four first output transistors Th1-Th4, four second output transistors Tl1-Tl4, and four output capacitors Cp1-Cp4. The first output transistors are provided in one-to-one correspondence with the control signal terminals. A gate of the first output transistor is connected to the control signal terminal corresponding to the first output transistor, a first electrode of the first output transistor is connected to the output clock signal terminal corresponding to the first output transistor, and a second electrode of the first output transistor is connected to the signal output terminal corresponding to the first output transistor. The second output transistors are provided in one-to-one correspondence with the signal output terminals. A gate of the second output transistor is connected to the first node, a first electrode of the second output transistor is connected to the second power supply terminal, and a second electrode of the second output transistor is connected to the signal output terminal corresponding to the signal output terminal. The output capacitors are provided in one-to-one correspondence with the control signal terminals. A first electrode of the output capacitor is connected to the control signal terminal corresponding to the output capacitor, and a second electrode of the output capacitor is connected to the signal output terminal corresponding to the output capacitor. The first output transistor and the output clock signal terminal corresponding to the same control signal terminal are provided in correspondence with each other. The first output transistor and the signal output terminal corresponding to the same control signal terminal are provided in correspondence with each other. The output capacitor and the signal output terminal corresponding to the same control signal terminal are provided in correspondence with each other.

In this exemplary embodiment, as shown in FIG. 3, the first pull-down circuit 7 can include a seventh transistor T7. A first electrode of the seventh transistor T7 is connected to the third clock signal terminal CLK3, a second electrode of the seventh transistor T7 is connected to the third node N3, and a gate of the seventh transistor T7 is connected to the second clock signal terminal CLK2.

In this exemplary embodiment, as shown in FIG. 3, the reset circuit 9 can include an eighth transistor T8 and a ninth transistor T9. A first electrode of the eighth transistor T8 is connected to the first power supply terminal VGH, a second electrode of the eighth transistor T8 is connected to the first node N1, and a gate of the eighth transistor T8 is connected to the reset signal terminal. A first electrode of the ninth transistor T9 is connected to the second power supply terminal VGL, a second electrode of the ninth transistor T9 is connected to the second node N2, and a gate of the ninth transistor T9 is connected to the reset signal terminal.

In this exemplary embodiment, as shown in FIG. 3, the second pull-down circuit 10 includes a tenth transistor T10. A first electrode of the tenth transistor T10 is connected to the third clock signal terminal CLK3, a second electrode of the tenth transistor T10 is connected to the first node N1, and a gate of the tenth transistor T10 is connected to any one of the control signal terminals.

As shown in FIGS. 3 and 4, the gate driver circuit can also include four clock signal lines CLKq1-CLKq4. Three of the clock signal lines CLKq1-CLKq4 respectively provide signals to the second clock signal terminal CLK2, the third clock signal terminal CLK3, and the fourth clock signal terminal CLK4. As shown in FIG. 4, for the first-stage shift register unit GOA, the second clock signal terminal CLK2 is connected to the clock signal line CLKq2, the third clock signal terminal CLK3 is connected to the clock signal line CLKq3, and the fourth clock signal terminal CLK4 is connected to the clock signal line CLKq4. For the second-stage shift register unit GOA, the second clock signal terminal CLK2 is connected to the clock signal line CLKq3, the third clock signal terminal CLK3 is connected to the clock signal line CLKq4, and the fourth clock signal terminal CLK4 is connected to the clock signal line CLKq1. For the third-stage shift register unit GOA, the second clock signal terminal CLK2 is connected to the clock signal line CLKq4, the third clock signal terminal CLK3 is connected to the clock signal line CLKq1, and the fourth clock signal terminal CLK4 is connected to the clock signal line CLKq2. For the fourth-stage shift register unit GOA, the second clock signal terminal CLK2 is connected to the clock signal line CLKq1, the third clock signal terminal CLK3 is connected to the clock signal line CLKq2, and the fourth clock signal terminal CLK4 is connected to the clock signal line CLKq3, and so on. For the fifth-stage shift register unit GOA, the second clock signal terminal CLK2 is connected to the clock signal line CLKq2, the third clock signal terminal CLK3 is connected to the clock signal line CLKq3, and the fourth clock signal terminal CLK4 is connected to the fourth clock signal line CLKq4.

As shown in FIGS. 3 and 4, the gate driver circuit can also include sixteen output clock signal lines CKq1-CKq16. In the shift register group GOAz, the sixteen output clock signal terminals of the four shift register units GOA are respectively connected to the sixteen output clock signal lines CKq1-CKq16. As shown in FIG. 4, for the first-stage shift register unit GOA, the output clock signal terminal CK1 is connected to the output clock signal line CKq1, the output clock signal terminal CK2 is connected to the output clock signal line CKq2, the output clock signal terminal CK3 is connected to the output clock signal line CKq3, and the output clock signal terminal CK4 is connected to the output clock signal line CKq4. For the second-stage shift register unit GOA, the output clock signal terminal CK1 is connected to the output clock signal line CKq5, the output clock signal terminal CK2 is connected to the output clock signal line CKq6, the output clock signal terminal CK3 is connected to the output clock signal line CKq7, and the output clock signal terminal CK4 is connected to the output clock signal line CKq8. For the third-stage shift register unit GOA, the output clock signal terminal CK1 is connected to the output clock signal line CKq9, the output clock signal terminal CK2 is connected to the output clock signal line CKq10, the output clock signal terminal CK3 is connected to the output clock signal line CKq11, and the output clock signal terminal CK4 is connected to the output clock signal line CKq12. For the fourth-stage shift register unit GOA, the output clock signal terminal CK1 is connected to the output clock signal line CKq13, the output clock signal terminal CK2 is connected to the output clock signal line CKq14, the output clock signal terminal CK3 is connected to the output clock signal line CKq15, and the output clock signal terminal CK4 is connected to the output clock signal line CKq16, and so on. For the fifth-stage shift register unit GOA, the output clock signal terminal CK1 is connected to the output clock signal line CKq1, the output clock signal terminal CK2 is connected to the output clock signal line CKq2, the output clock signal terminal CK3 is connected to the output clock signal line CKq3, and the output clock signal terminal CK4 is connected to the output clock signal line CKq4.

In this exemplary embodiment, all the transistors in the shift register unit shown in FIG. 3 are N-type transistors. The first power supply terminal VGH can be a high-level power supply terminal, and the second power supply terminal VGL can be a low-level power supply terminal.

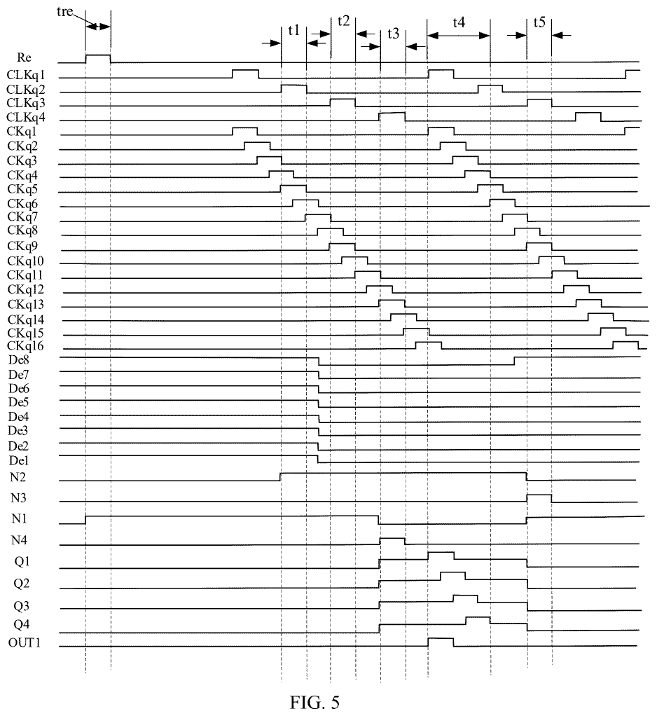

According to an exemplary embodiment, a driving method is provided for the shift register unit. As shown in FIG. 5, it is a timing diagram of each signal line and node in a driving method of the shift register unit of the present disclosure. The timing diagram shown in FIG. 5 is the timing diagram when the first-stage shift register unit in the gate driver circuit shown in FIG. 4 is selected. Here, “Re” denotes the timing diagram of the reset signal terminal Re, “CLKq1” to “CLKq4” denote respectively the timing diagrams of the clock signal lines CLKq1-CLKq4, “CKq1” to “CKq16” denote respectively the timing diagrams of the output clock signal lines CKq1-CKq16, “D1e” to “D8e” denote respectively the timing diagrams of the gating signal lines D1e-D8e, “N1” denotes the timing diagram of the first node, “N2” denotes the timing diagram of the second node, “N3” denotes the timing diagram of the third node, “N4” denotes the timing diagram of the fourth node, “Q1” to “Q4” denote respectively the timing diagrams of the control signal terminals Q1-Q4, and “OUT1” to “OUT4” denote respectively the timing diagrams of the signal output terminals OUT1-OUT4.

Before the display period of the display panel, there can be a reset phase tre. In the reset phase tre, the reset signal terminal Re outputs a high-level signal, the eighth transistor T8 and the ninth transistor T9 are turned on, the high-level signal from the first power supply terminal VGH resets the first node N1, and the low-level signal from the second power supply terminal VGL resets the second node N2.

As shown in FIG. 5, the display period of the display panel can include a first phase t1, a second phase t2, a third phase t3, a fourth phase t4, and a fifth phase t5.

In the first phase t1, the clock signal line CLKq2 outputs a high-level signal, and the clock signal lines CLKq3 and CLKq4 output low-level signals, the gating signal lines De1-De8 all output high-level signals, the clock signal line CLKq2 inputs the high-level signal to the second node N2, and the clock signal line CLKq3 inputs the low-level signal to the third node N3. The first node N1 maintains the high level of the previous phase. The second power supply terminal VGL outputs low-level signals to the signal output terminals OUT1-OUT4 through the second output transistors Tl1-Tl4 respectively. At the same time, the second power supply terminal VGL inputs low-level signals to the control signal terminals Q1-Q4 through the separation transistors Tp1-Tp4 respectively. In addition, the seventh transistor T7 is turned on, and the clock signal line CLKq3 inputs the low-level signal to the third node N3.

In the second phase t2, the clock signal line CLKq3 outputs a high-level signal, and the clock signal lines CLKq2 and CLKq4 output low-level signals. If the shift register unit is selected, the gating signal lines De1-De8 all output low-level signals. The second node N2 maintains the high-level signal of the previous phase. The clock signal line CLKq3 writes the high-level signal to the first node N1. The second power supply terminal VGL outputs low-level signals to the signal output terminals OUT1-OUT4 through the second output transistors Tl1-Tl4 respectively. At the same time, the second power supply terminal VGL inputs the low-level signals to the control signal terminals Q1-Q4 through the separation transistors Tp1-Tp4 respectively.

In the third phase t3, the clock signal line CLKq4 outputs a high-level signal, and the clock signal lines CLKq2 and CLKq3 output low-level signals. The clock signal line CLKq4 writes the high-level signal to the fourth node N4 through the sixth transistor T6, and the fourth node N4 inputs the high-level signal to the control signal terminals Q1-Q4 through the input transistors Ti1-Ti4 respectively. At the same time, the clock signal line CLKq3 inputs the low-level signal to the first node N1 through the tenth transistor T10, and the clock signal line CLKq3 inputs the low-level signal to the first node N1 through the second transistor T2 and the third transistor T3.

In the fourth phase t4, the control signal terminals Q1-Q4 maintain the high level. The output clock signal lines CKq1-CKq4 respectively output high-level signals to the signal output terminals OUT1-OUT4 through the first output transistors Th1-Th4 in sequence.

In the fifth phase t5, the clock signal line CLKq3 outputs a high-level signal, and the clock signal lines CLKq2 and CLKq4 output low-level signals. The clock signal line CLKq3 inputs the high-level signal to the first node N1, and the separation transistors Tp1-Tp4 are turned on. The second power supply terminal VGL inputs low-level signals to the control signal terminals Q1-Q4 through the separation transistors Tp1-Tp4 respectively. At the same time, the second power supply terminal VGL outputs the low-level signals to the signal output terminals OUT1-OUT4 through the second output transistors Tl1-Tl4 respectively. In addition, the gating signal line De8 outputs a high-level signal, the gating transistor Td8 is turned on, and the clock signal line CLKq3 inputs a high-level signal to the third node N3.

If the shift register unit is not selected, in the above-mentioned second phase, at least one of the gating signal lines De1-De8 outputs a high-level signal, the clock signal line CLKq3 inputs a high-level signal to the third node N3, the fifth transistor T5 is turned on, and the clock signal line CLKq2 writes a low-level signal to the second node N2. In this way, the clock signal line CLKq4 will not write a high-level signal to the fourth node in the third phase, and thus, the signal output terminal will not output a high-level signal in the fourth phase.

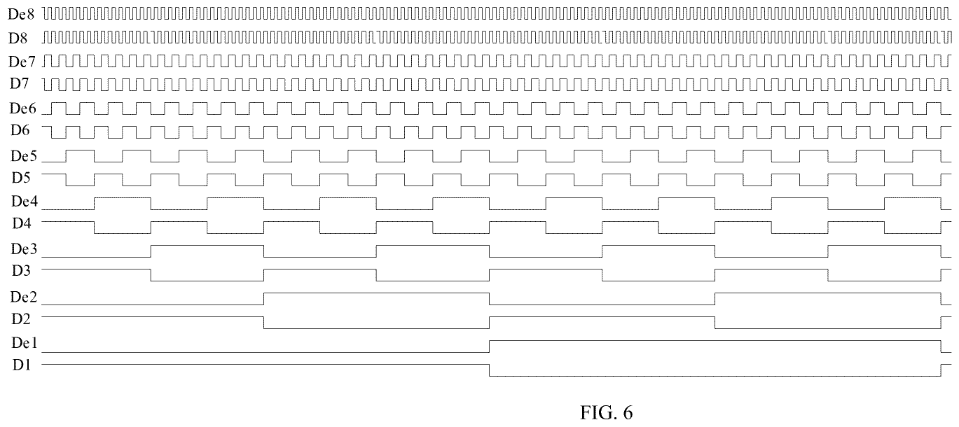

As shown in FIG. 6, it is a timing diagram of eight pairs of gating signal lines in the timing diagram shown in FIG. 5. Here, “D1e” to “D8e” denote respectively the timing diagrams of the gating signal lines D1e to D8e, and “D1” to “D8” denote respectively the timing diagrams of the gating signal lines D1 to D8. Die and Di form a pair of gating signal lines, where i is an integer greater than or equal to 1 and less than or equal to 8. The polarities of the two gating signal lines in the same pair of gating signal lines are opposite. In this exemplary embodiment, the low-level pulse duration of the gating signal line Di is longer than the low-level pulse duration of the gating signal line Di+1. For example, the low-level pulse duration of the gating signal line Di is the double of the low-level pulse duration of the gating signal line Di+1.

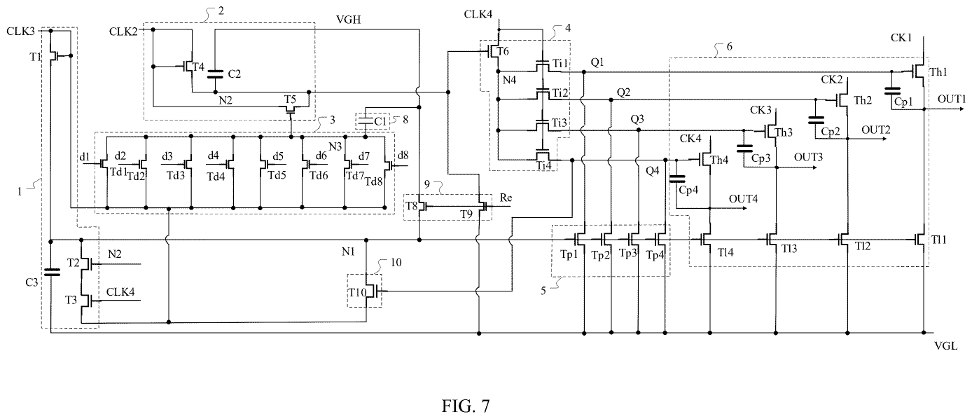

As shown in FIG. 7, it is a structural schematic diagram of a shift register unit according to an exemplary embodiment of the present disclosure. Compared with the shift register unit shown in FIG. 3, the shift register unit shown in FIG. 7 does not have a first pull-down circuit 7, but is provided with a first storage circuit 8. The first storage circuit 8 is connected to the third node N3, and the first storage circuit 8 is configured to store the voltage at the third node N3. The first storage circuit 8 can store the voltage at the third node N3, so that the voltage, in the first phase t1, at the third node N3 can be maintained at the voltage of the previous phase. With this setting, the first pull-down circuit 7 can be omitted.

In this exemplary embodiment, as shown in FIG. 7, the first storage circuit 8 can include a first capacitor C1. A first electrode of the first capacitor C1 is connected to the third node N3, and a second electrode of the first capacitor C1 is connected to a stable voltage terminal. For example, the second electrode of the first capacitor C1 can be connected to the first power supply terminal VGH. The driving method of the shift register unit shown in FIG. 7 can be the same as that of the shift register unit shown in FIG. 3.

In this exemplary embodiment, the node setting circuit 1, the preprocessing circuit 2, the gating circuit 3, the input circuit 4, the separation circuit 5, the output circuit 6, the first pull-down circuit 7, the reset circuit 9, and the second pull-down circuit 10 in the shift register units shown in FIGS. 3 and 7 can also have other connection methods or structures.

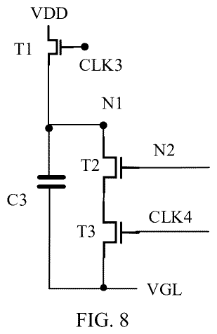

As shown in FIG. 8, it is a structural schematic diagram of a node setting circuit of a shift register unit according to another exemplary embodiment of the present disclosure. The node setting circuit 1 can be connected to a third power supply terminal VDD, and the node setting circuit 1 can respond to the signal from the third clock signal terminal CLK3 to input an effective level to the first node N1 using the third power supply terminal VDD, and the first power supply terminal VGH can be reused as the third power supply terminal VDD. And/or, the node setting circuit 1 can be connected to the second power supply terminal VGL, and the node setting circuit 1 can respond to the signals from the second node N2 and the fourth clock signal terminal CLK4 to input an invalid level to the first node N1 by using the second power supply terminal VGL. In addition, the node setting circuit 1 can also be provided without the second transistor T2 and the third transistor T3.

In other exemplary embodiments, the first pull-down circuit 7 can also have other connection methods. For example, the first pull-down circuit 7 can be connected to the second power supply terminal VGL, and the first pull-down circuit can be configured to respond to the signal from the second clock signal terminal to input an invalid level to the third node N3 using the second power supply terminal VGL. The second pull-down circuit 10 can have other connection methods. For example, the second pull-down circuit 10 is also connected to the second power supply terminal VGL, and the second pull-down circuit is configured to respond to the signal from the control signal terminal to input an invalid level to the first node N1 using the second power supply terminal VGL. The preprocessing circuit 2 can have other connection methods. For example, the preprocessing circuit 2 can be configured to respond to the signal from the second clock signal terminal to provide an effective level to the second node using the first power supply terminal VGH.

In this exemplary embodiment, in the same shift register unit, the types of the gating transistors Td1-Td8 are the same. It should be understood that in other exemplary embodiments, the types of the gating transistors Td1-Td8 can be at least partially different. For example, some gating transistors are P-type transistors and some gating transistors are N-type transistors. By setting the types of gating transistors, different conduction combinations can be achieved even when different shift register units are connected to the same gating signal line. Different conduction combinations can be understood as that at least one transistor has a different conduction state. For example, in one shift register unit, the gating transistors Td1-Td7 are N-type transistors and the gating transistor Td8 is a P-type transistor, while in another shift register unit, the gating transistors Td1-Td8 are all N-type transistors. In this way, even if the two shift register units are connected to the same 8 gating signal lines, at least one of the gating transistors Td1-Td8 has a different gating state. Wi^{th} this setting, arbitrary selection of the shift register group can be achieved with fewer gating signal lines.

In this exemplary embodiment, in different shift register groups, at least a portion of the shift register units have different combinations of types of gating transistors. The shift register unit includes n gating signal terminals, and the gate driver circuit includes 2ⁿ shift register groups and n gating signal lines. The n gating signal terminals are provided in one-to-one correspondence with the n gating signal lines, and the gating signal terminal is connected to the corresponding gating signal line. In different shift register groups, the combinations of types of gating transistors in the shift register units are all different.

In this exemplary embodiment, the same gating signal line is respectively connected to 2ⁿ/2 N-type transistors and 2ⁿ/2 P-type transistors. Among multiple shift register groups that are simultaneously connected to the first to the i^{th} gating signal lines and have the same type of gating transistors connected to the same gating signal line, half of the gating transistors connected to the (i+1)^{th} gating signal line are N-type transistors and half of the gating transistors are P-type transistors, i being an integer greater than or equal to 1 and less than or equal to n−1. For example, Td1 in the 1^{st} to the (2ⁿ/2)^{th} shift register groups is an N-type transistor, and Td1 in the (2ⁿ/2+1)^{th} to the (2ⁿ)^{th} shift register groups is a P-type transistor; Td2 in the 1^{st} to the (2ⁿ/4)^{th} shift register groups and the (2ⁿ/2+1)^{th} to the (3*2ⁿ/4)^{th} shift register groups is an N-type transistor, and Td2 in the (2ⁿ/4+1)^{th} to the (2ⁿ/2)^{th} shift register groups and the (3*2ⁿ/4+1)^{th} to the (2ⁿ)^{th} shift register groups is a P-type transistor; and so on. This setting can achieve that in different shift register groups, the combinations of types of gating transistors in the shift register units are all different.

In this exemplary embodiment, the number of shift register units in different shift register groups can be the same or different.

According to an exemplary embodiment, a display panel is also provided. The display panel can include the gate driver circuit described above, and this display panel can be applied to display devices such as mobile phones, tablet computers, and televisions.

According to an exemplary embodiment, a display device is also provided. The display device includes the display panel described above.

Those skilled in the art, after considering the specification and practicing the content disclosed herein, will easily conceive of other embodiments of the present disclosure. This application aims to cover any variations, uses, or adaptive changes of the present disclosure. These variations, uses, or adaptive changes follow the general principles of the present disclosure and include common knowledge or conventional technical means in the technical field of the present disclosure that are not disclosed. The specification and embodiments are only regarded as exemplary, and the true scope and spirit of the present disclosure are pointed out by the claims.

It should be understood that the present disclosure is not limited to the precise structure described above and shown in the drawings, and various modifications and changes can be made without departing from its scope. The scope of the present disclosure is only defined by the appended claims.

1. A shift register unit, comprising:
a node setting circuit, connected to a third clock signal terminal and a first node, and configured to input an effective level to the first node in response to a signal from the third clock signal terminal;
a preprocessing circuit, connected to a second clock signal terminal, a second node, and a third node, and configured to input an effective level to the second node in response to a signal from the second clock signal terminal, and to transmit the signal from the second clock signal terminal to the second node in response to a signal from the third node;
a gating circuit, connected to the third node, the third clock signal terminal, and one or more gating signal terminals, and configured to transmit the signal from the third clock signal terminal to the third node in response to a signal from one of the one or more gating signal terminals;
an input circuit, connected to a fourth clock signal terminal, the second node, and one or more of a plurality of control signal terminals, and configured to transmit a signal from the fourth clock signal terminal to the one or more control signal terminals in response to a signal from the second node;
a separation circuit, connected to the first node, the plurality of control signal terminals, and a second power supply terminal, and configured to transmit a signal from the second power supply terminal to the plurality of control signal terminals in response to a signal from the first node; and
an output circuit, connected to the plurality control signal terminals, a plurality of output clock signal terminals, a plurality of signal output terminals, and the second power supply terminal, wherein the plurality of control signal terminals are provided in correspondence with the plurality of output clock signal terminals, and the plurality of control signal terminals are provided in correspondence with the plurality of signal output terminals; and the output circuit is configured to transmit, according to a signal from the control signal terminal, a signal from the output clock signal terminal corresponding to the control signal terminal to the signal output terminal corresponding to the control signal terminal, and to transmit the signal from the second power supply terminal to the plurality of signal output terminals in response to the signal from the first node.

2. The shift register unit according to claim 1, further comprising at least one of following circuits:
a first pull-down circuit, connected to the third node and the second clock signal terminal, and configured to input an invalid level to the third node in response to the signal from the second clock signal terminal;
a first storage circuit, connected to the third node, and configured to store a voltage at the third node;
a reset circuit, connected to a first power supply terminal, the first node, the second node, the second power supply terminal, and a reset signal terminal, and configured to transmit a signal from the first power supply terminal to the first node in response to a signal from the reset signal terminal, and to transmit the signal from the second power supply terminal to the second node in response to the signal from the reset signal terminal; or
a second pull-down circuit, connected to one of the plurality of control signal terminals and the first node, and configured to input an invalid level to the first node in response to a signal from the control signal terminal.

3-5. (canceled)

6. The shift register unit according to claim 1, wherein the node setting circuit is further connected to the fourth clock signal terminal and the second node, and configured to provide an invalid level to the first node using the third clock signal terminal in response to the signal from the fourth clock signal terminal and the signal from the second node.

7. The shift register unit according to claim 1, wherein the node setting circuit is configured to provide the effective level to the first node using the third clock signal terminal in response to the signal from the third clock signal terminal.

8. (canceled)

9. The shift register unit according to claim 2, wherein the first pull-down circuit is further connected to the third clock signal terminal, and configured to input the invalid level to the third node using the third clock signal terminal in response to the signal from the second clock signal terminal,
wherein the first pull-down circuit comprises:
a seventh transistor, with a first electrode connected to the third clock signal terminal, a second electrode connected to the third node, and a gate connected to the second clock signal terminal.

10. The shift register unit according to claim 2, wherein the second pull-down circuit is further connected to the third clock signal terminal, and configured to input the invalid level to the first node using the third clock signal terminal in response to the signal from the control signal terminal.

11. The shift register unit according to claim 1, wherein the preprocessing circuit is configured to provide the effective level to the second node using the second clock signal terminal in response to the signal from the second clock signal terminal.

12. The shift register unit according to claim 1, wherein
the node setting circuit comprises: a first transistor, with a first electrode connected to the third clock signal terminal, a second electrode connected to the first node, and a gate connected to the third clock signal terminal; a second transistor, with a first electrode connected to the first node, and a gate connected to the second node; a third transistor, with a first electrode connected to a second electrode of the second transistor, and a second electrode connected to the third clock signal terminal; and a third capacitor, with a first electrode connected to the first node, and a second electrode connected to a stable voltage terminal;
the preprocessing circuit comprises: a fourth transistor, with a first electrode connected to the second clock signal terminal, a second electrode connected to the second node, and a gate connected to the second clock signal terminal; a fifth transistor, with a first electrode connected to the second clock signal terminal, a second electrode connected to the second node, and a gate connected to the third node; and a second capacitor, with a first electrode connected to the second node, and a second electrode connected to a stable voltage terminal.

13. (canceled)

14. The shift register unit according to claim 1, wherein
the gating circuit comprises: one or more gating transistors, wherein the one or more gating transistors are provided in correspondence with the one or more gating signal terminals; and a first electrode of the gating transistor is connected to the third clock signal terminal, a second electrode of the gating transistor is connected to the third node, and a gate of the gating transistor is connected to the gating signal terminal corresponding to the gating transistor;
the input circuit comprises: a sixth transistor, with a first electrode connected to the fourth clock signal terminal, a second electrode connected to a fourth node, and a gate connected to the second node; and one or more input transistors, wherein the one or more input transistors are provided in correspondence with the one or more control signal terminals; and a first electrode of the input transistor is connected to the fourth node, a second electrode of the input transistor is connected to the control signal terminal corresponding to the input transistor, and a gate of the input transistor is connected to the fourth clock signal terminal; and
the separation circuit comprises: one or more separation transistors provided in correspondence with the plurality of control signal terminal, wherein a first electrode of the separation transistor is connected to the second power supply terminal, a second electrode of the separation transistor is connected to the control signal terminal corresponding to the separation transistor, and a gate of the separation transistor is connected to the first node.

15-16. (canceled)

17. The shift register unit according to claim 1, wherein the output circuit comprises:
one or more first output transistors provided in correspondence with the plurality of control signal terminals, wherein a gate of the first output transistor is connected to the control signal terminal corresponding to the first output transistor, a first electrode of the first output transistor is connected to the output clock signal terminal corresponding to the first output transistor, and a second electrode of the first output transistor is connected to the signal output terminal corresponding to the first output transistor;
one or more second output transistors provided in correspondence with the plurality of signal output terminals, wherein a gate of the second output transistor is connected to the first node, a first electrode of the second output transistor is connected to the second power supply terminal, and a second electrode of the second output transistor is connected to the signal output terminal corresponding to the second output transistor; and
one or more output capacitors provided in correspondence with the plurality of control signal terminals, wherein a first electrode of the output capacitor is connected to the control signal terminal corresponding to the output capacitor, and a second electrode of the output capacitor is connected to the signal output terminal corresponding to the output capacitor;
wherein, the first output transistor and the output clock signal terminal corresponding to the same control signal terminal are provided in correspondence with each other, the first output transistor and the signal output terminal corresponding to the same control signal terminal are provided in correspondence with each other, and the output capacitor and the signal output terminal corresponding to the same control signal terminal are provided in correspondence with each other.

18. (canceled)

19. The shift register unit according to claim 2, wherein
the first storage circuit comprises: a first capacitor, with a first electrode connected to the third node, and a second electrode connected to a stable voltage terminal;
the reset circuit comprises: an eighth transistor, with a first electrode connected to the first power supply terminal, a second electrode connected to the first node, and a gate connected to the reset signal terminal; and a ninth transistor, with a first electrode connected to the second power supply terminal, a second electrode connected to the second node, and a gate connected to the reset signal terminal.

20. (canceled)

21. The shift register unit according to claim 10, wherein the second pull-down circuit comprises:
a tenth transistor, with a first electrode connected to the third clock signal terminal, a second electrode connected to the first node, and a gate connected to the control signal terminal.

22. (canceled)

23. A driving method of a shift register unit, for driving the shift register unit according to claim 1, the driving method comprising:
in a first phase, inputting the effective level to the second node using the preprocessing circuit;
in a second phase, when the shift register unit is selected, turning off a connection between the third clock signal terminal and the third node using the gating circuit; when the shift register unit is not selected, turning on the connection between the third clock signal terminal and the third node using the gating circuit;
in a third phase, when the shift register unit is selected, transmitting the signal from the fourth clock signal terminal to the one or more control signal terminals using the input circuit; when the shift register unit is not selected, turning off an connection between the fourth clock signal terminal and each of the one or more control signal terminals using the input circuit;
in a fourth phase, when the shift register unit is selected, transmitting, according to the signal from the control signal terminal, the signal from the output clock signal terminal corresponding to the control signal terminal to the signal output terminal corresponding to the control signal terminal using the output circuit; when the shift register unit is not selected, turning off an connection between the fourth clock signal terminal and each of the plurality of signal output terminals using the output circuit, and transmitting the signal from the second power supply terminal to the signal output terminal using the output circuit; and
in a fifth phase, transmitting the signal from the second power supply terminal to the plurality of control signal terminals using the separation circuit, and transmitting the signal from the second power supply terminal to the plurality of signal output terminals using the output circuit.

24. A gate driver circuit, comprising a plurality of shift register units each according to claim 1.

25. The gate driver circuit according to claim 24, comprising:
a plurality of shift register groups, each shift register group comprises one or more of the plurality of shift register units;
a plurality of gating signal lines, wherein
in a same shift register unit, different gating signal terminals are respectively connected to different gating signal lines;
in a same shift register group, the shift register units are connected to a same gating signal line; and
in different shift register groups, at least one of the gating signal lines connected to the shift register units is different.

26. The gate driver circuit according to claim 25, wherein in different shift register groups, at least a portion of the plurality of shift register units are connected to a same gating signal line.

27. The gate driver circuit according to claim 25, wherein the shift register unit comprises n gating signal terminals, n being an integer greater than or equal to 1, the gate driver circuit comprises 2ⁿ shift register groups and n pairs of gating signal lines, each pair of gating signal lines comprises two gating signal lines, and the two gating signal lines in a same pair of gating signal lines are respectively connected to 2ⁿ/2 shift register groups; and
the n gating signal terminals in the shift register unit are provided in one-to-one correspondence with the n pairs of gating signal lines, and the gating signal terminal is selectively connected to one of the gating signal lines in the corresponding pair of gating signal lines; and
wherein, polarities of the two gating signal lines in the same pair of gating signal lines are opposite.

28. The gate driver circuit according to claim 27, wherein, when n is greater than or equal to 2,
the n pairs of gating signal lines comprise a first pair of gating signal lines to an nth pair of gating signal lines, and among multiple shift register groups that are simultaneously connected to a same gating signal line in the first to an i^{th} pairs of gating signal lines, half of the multiple shift register groups are connected to one of the gating signal lines in a (i+1)^{th} pair of gating signal lines, and the other half of the multiple shift register groups are connected to the other gating signal line in the (i+1)^{th} pair of gating signal lines, i being an integer greater than or equal to 1 and less than or equal to n−1.

29. The gate driver circuit according to claim 24, wherein, when the gating circuit comprises one or more gating transistors, the one or more gating transistors are provided in correspondence with the one or more gating signal terminals, a first electrode of the gating transistor is connected to the third clock signal terminal, a second electrode of the gating transistor is connected to the third node, and a gate of the gating transistor is connected to the gating signal terminal corresponding to the gating signal terminal;
the gate driver circuit comprises a plurality of shift register groups, each shift register group comprising one or more of the plurality of shift register units; and
in different shift register groups, at least a portion of the plurality of shift register units have different combinations of types of gating transistors.

30-32. (canceled)

33. A display panel, comprising the gate driver circuit according to claim 24.
